(19) United States
(12) Patent Application Publication
(10) Pub. No.: US 2012/0320085 A1
(43) Pub. Date: Dec. 20, 2012

(54) Display outputting image

(76) Inventors: Ping Mei, San Jose, CA (US); Warren Jackson, San Francisco, CA (US)

(21) Appl. No.: 13/068,059

(22) Filed: Apr. 29, 2011

(51) Int. Cl. G09G 5/00; H05K 3/36; G06F 3/041

(52) U.S. Cl. 345/629; 345/173; 29/830

(57) ABSTRACT

Example embodiments disclosed herein relate to display outputting a user interface.

### BACKGROUND

An increase in processing power, memory and display sizes of computing devices have led to increased functionality and/or greater interactivity. Device manufacturers of computing devices, such as mobile devices, are challenged to provide user interfaces that allow a user to interact with the computing device more conveniently and/or efficiently.

### BRIEF DESCRIPTION OF THE DRAWINGS

The following detailed description references the drawings, wherein:

FIG. 1A is an example block diagram of a perspective view of a display device according to a first configuration;

FIG. 1B is an example block diagram of a perspective view of the display device according to a second configuration;

FIG. 2A is an example block diagram of a front-view of the display device of FIG. 1A showing the user interface activated;

FIG. 2B is an example block diagram of a front-view of the display device of FIG. 1A showing the user interface deactivated;

FIG. 3A is an example block diagram of a perspective view of another display device;

FIG. 3B is an example block diagram of a cross-sectional side-view of the display device of FIG. 3A;

FIG. 4A is an example block diagram of a perspective view of yet another display device;

FIG. 4B is an example block diagram of a cross-sectional side-view of the display device of FIG. 4A;

FIG. 4C is an example block diagram of an exposed top-view of the display device of FIG. 4A; and

FIG. 5 is a flowchart of an example method for forming a display device.

### DETAILED DESCRIPTION

Specific details are given in the following description to provide a thorough understanding of embodiments. However, it will be understood by one of ordinary skill in the art that embodiments may be practiced without these specific details. For example, systems may be shown in block diagrams in order not to obscure embodiments in unnecessary detail. In other instances, well-known processes, structures and techniques may be shown without unnecessary detail in order to avoid obscuring embodiments.

User interfaces, such as keyboards, for computing devices, such as mobile devices, may be inefficient or inconvenient to use. For example, mobile devices having dedicated keyboards, such as pull-out keyboards, generally have relatively small physical keys due to size limitations of the mobile devices. As a result, typos may occur more often and/or typing may be inconvenient and/or slow, such as when a user uses fingernails to press the keys.

Larger dedicated keyboards, such as folding keyboards, generally require use of both hands of the user to type and/or fold/unfold the keyboard. On the other hand, virtual keyboards displayed as an image on a display may compete for space due to a limited size of the display. For instance, virtual keys of a virtual keyboard may be too small. Also, visibility of other images may be blocked and/or a viewing area of the other images may be reduced, when the virtual keyboard is shown on the display.

User interfaces may also provide touch feedback that horizontally vibrates an entire surface of the display in response to being touched by the user. However, these vibrations may reduce a visibility of an image being shown, such as at a portion of the display not related to the touch. For example, visibility of typed text shown above the virtual keyboard of the display may be reduced during these vibrations.

Moreover, the touch feedback does not allow the user to differentiate between touches to different regions of the display and/or simultaneous multiple touches to the display. In addition, the horizontal or side-to-side vibration may not adequately convey to the user that the key of the virtual keyboard is being pressed or depressed. As a result, the user may find the virtual keyboard to be less responsive and more error-prone.

Embodiments provide a user interface that allows the user to interact with the computing device more conveniently and/or efficiently. For example, an embodiment may allow the user to operate the mobile device with only one hand while providing sufficiently large buttons. Further, an entire surface of the display may be utilized simultaneously for the both user input to the user interface and displaying images.

In another embodiment, touch feedback may be provided independently and/or locally to different regions of the surface of the display. Thus, the user may be able to differentiate between touches to different regions of the display and/or simultaneous multiple touches to the display, resulting in greater responsiveness and/or accuracy for the user.

Also, in an embodiment, the touch feedback may be provided in a vertical direction with respect to a surface the display, thus more accurately conveying to the user that a button of the user interface is being pressed down and/or depressed up. Further, different regions of the surface of the display may move independently of one another. Accordingly, visibility of an image shown at one region of the display may not be affected or be less affected by a touch and/or press to another region of the display.

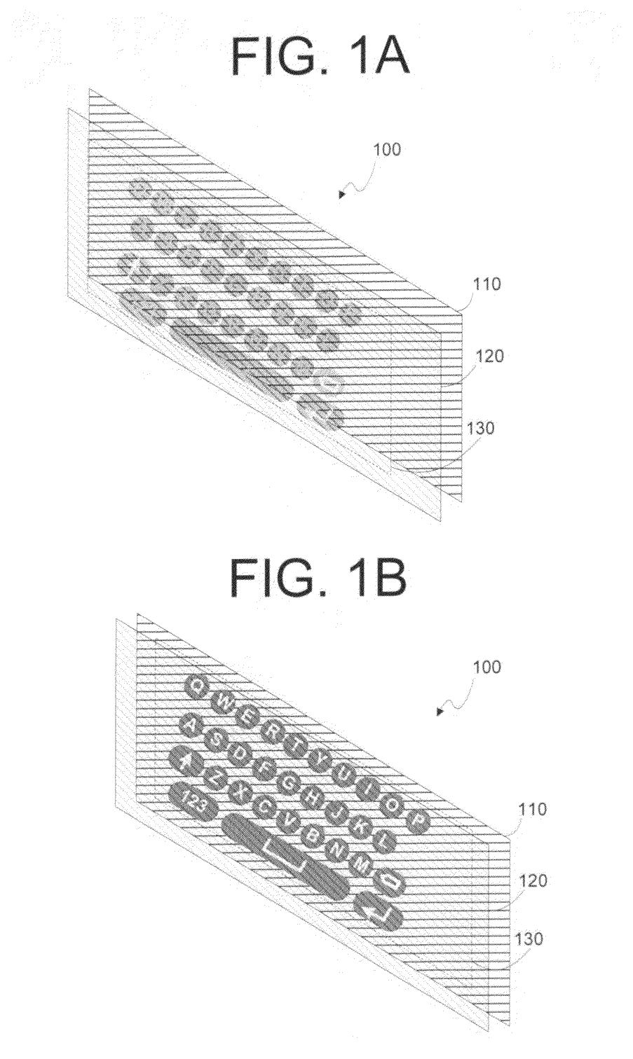

Referring now to the drawings, FIG. 1A is an example block diagram of a perspective view of a display device 100 according to a first configuration. In the embodiment of FIG. 1A, the display device 100 includes a first display 110 and a second display 120 overlapping the first display 110. The first display 110 is to output a first image (not shown) and the second display 120 is to output a second image 130.

The second display 120 is transparent and the second image 130 corresponds to a user interface, such as a keyboard shown in FIG. 1A. However, embodiments are not limited thereto and may include various other types of user interfaces, such as other types of keyboards, a gaming interface, etc. Further, embodiments of the user interface may include various shapes, sizes, colors, etc.

The second display 120 may also include a touch sensitive surface (not shown) to allow a user to interact with the user interface 130. Examples of technologies related to the touch sensitive surface may include surface acoustic wave technology, resistive touch technology, capacitive touch technology, infrared touch technology, dispersive signal technology, acoustic pulse recognition technology, various multi-touch technologies, and the like.

The term display may refer to any type of electronic visual display. Examples of the display may include an integrated display device, such as a Liquid Crystal Display (LCD) panel or other type of display panel. The term display may also include one or more external display devices, such as an LCD panel, a plasma panel, a Cathode Ray Tube (CRT) display, a flexible display, a rigid display, or any other display device. Flexible displays may include any type of display composed of a flexible substrate that can bend, flex, conform, etc., such as organic light emitting diode (OLED) or electronic ink displays. A rigid display may include any type of display having a rigid surface that cannot bend, flex, conform, etc., such as LCDs or CRTs. Transparent displays may be any type of display composed of transparent material that the user can see through, such as liquid crystal or OLED displays.

The first image and the second image 130 may be any type of visual displayed by the first or second displays 110 or 120. The first and second displays 110 and 120 may be powered by a computing device (no shown), where the first and second displays 110 and 120 may be separate from or integrated with the computing device. The computing device may also transmit the first and second images and/or other data to the first and/or second displays 110 and 120. Examples of a computing device may include, for example, a notebook computer, a desktop computer, an all-in-one system, a slate computing device, a portable reading device, a wireless email device, a mobile phone, and the like designed to help the user to perform singular or multiple related specific tasks.

The first image and/or the second image 130 may respond to a touch by the user to the touch sensitive surface of the second display 120. The touch sensitive surface may communicate data and/or signals to the computing device. The computing device may interpret the data and/or signals to control an output of the first image and/or the second image 130. For example, if the user touches a key of the keyboard shown on the second display 120, the touched key may be shown as typed text in the first image shown on the first display 110.

The computing device may include one or more central processing units (CPUs), semiconductor-based microprocessors, and/or other hardware devices suitable for access and execution of instructions stored in a machine-readable storage medium. The machine-readable storage medium may be any electronic, magnetic, optical, or other physical storage device. For example, the machine-readable storage medium may store one or more of the applications for correlating a presence and location of the touch by the user at the touch sensitive surface to one or more buttons of the user interface 130.

The terms button and key may be used interchangeably and a key may represent a type of button. Further, the terms key and button may refer to at least one of the interactive elements included and shown in the user interface 130 and/or keyboard.

As shown in FIG. 1A, the user interface or keyboard 130 is partially transparent. As a result, the user using the display device 100 may be able to see both the user interface 130 in the foreground and the first image in the foreground simultaneously over a same surface area of the display device 100. A transparency of the user interface 130 may be variable and range from being, for example, fully opaque to fully transparent. However, a fully transparent user interface 130 may not be visible to the user and a fully opaque user interface 130 may block visibility of the first image. The transparency of the user interface 130 may be varied automatically by the computing device, for example, to optimize or improve simultaneous viewing of the user interface 130 and the first image, or manually according to the user's preference. For instance, the transparency may be varied based on color, contrast, ambient light, etc.

Embodiments may include the first and second displays 110 and 120 to different resolution capabilities. Higher resolution capabilities may be desirable when viewing complex or detailed images, such as photographic images, but unnecessary when viewing simple images. Thus, when the user interface 130 is relatively simple, a high-resolution display may not be necessary. In one embodiment, the first display 110 may be a high-resolution display and the second display 120 may be a low-resolution display.

Further, the second display 120 may also be monochromatic or electrochromic. In addition, the user interface 130 may be embedded into the second display 120 so that the button or keys of the user interface 130 are predefined. For example, a small number of liquid crystal segments may be prearranged in the second display 120 to only output a limited number of display elements, such as only the buttons of the user interface 130. Thus, embodiments may reduce operating and/or manufacturing costs of the display device 100 by using a lower resolution and/or simpler display for the second display 120.

The first and second displays 110 and 120 may be any combination of rigid and flexible displays. Moreover, the second display 120 may be removable and/or interchangeable with a third display (not shown). For example, the second display 120 may peel off when composed of a flexible display or slide off when composed of a rigid display. Similarly, the third display may be rolled on when composed of a flexible display or slide on when composed of a rigid display. The third display may be similar the second display 120. In one embodiment, the third display may be embedded with a different type of user interface than that of the second display 120. In this case, the user may be able to quickly and/or inexpensively swap out different and/or customized user interfaces.

FIG. 1B is an example block diagram of a perspective view of the display 100 according to a second configuration. In this configuration, the first display 110 is to output the user interface 130 as the first image. Thus, while the first configuration of FIG. 1A shows the user interface 130 in the foreground, the second configuration of FIG. 1B shows the user interface 130 in the background.

Hence, the display device 100 may dynamically swap the first and second images between the first and second displays 110 and 120. For example, it may be preferable to switch the user interface 130 to either the foreground or background based on a type of content being displayed or according to the user's preference.

In one embodiment, both the first and second displays 110 and 120 may be high-resolution displays. As such, image quality of one of the first and second images may not degrade when dynamically switched to another of the first and second displays 110 and 120.

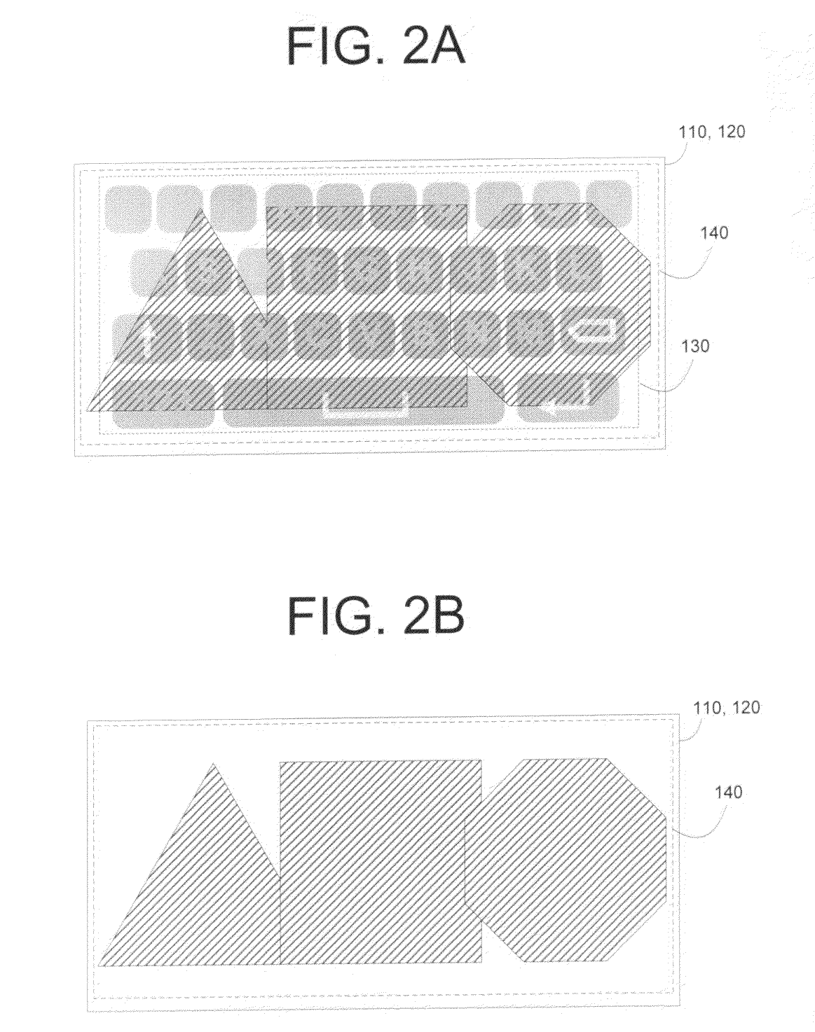

FIG. 2A is an example block diagram of a front-view of the display 100 of FIG. 1A showing the user interface 130 activated and FIG. 2B is an example block diagram of a front-view of the display of FIG. 1A showing the user interface 130 deactivated. As shown in FIG. 2A, both the first image 140 of the first display 110 and the activated user interface 130 of the second display 120 are simultaneously visible over a same surface area of the display device 100, where the first image 140 is behind the user interface 130. As shown in FIG. 2B, when the user interface 130 is deactivated, the user interface 130 becomes invisible or nearly invisible, and the first image 140 is clearly visible through the transparent second display 120. The user interface 130 may be activated or deactivated automatically by the computing device or user input, such as a touch or gesture by the user at the touch sensitive surface of the second display 120.

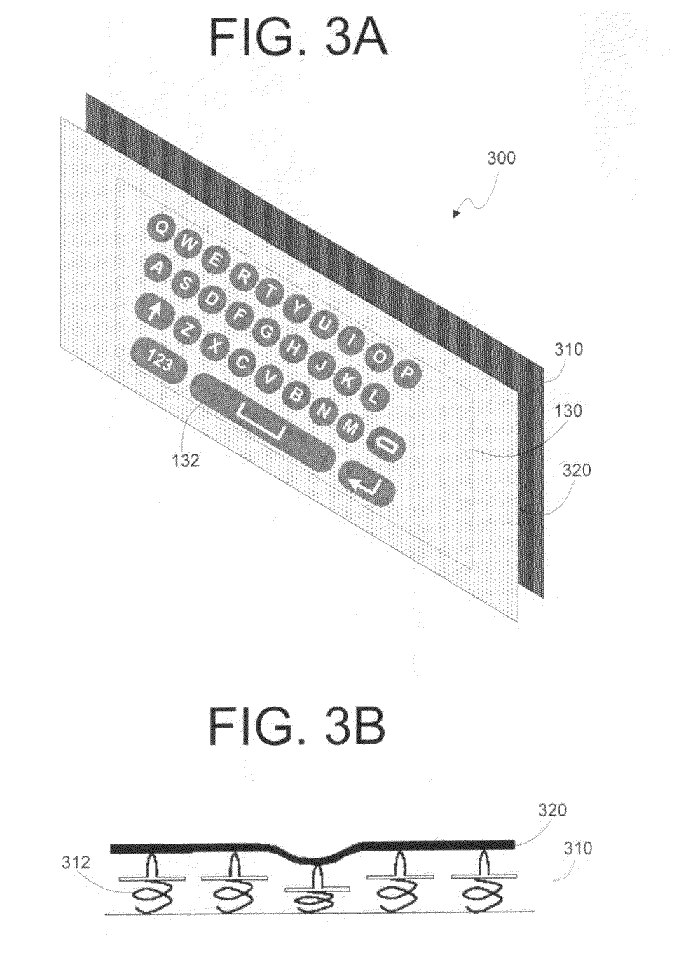

FIG. 3A is an example block diagram of a perspective view of another display device 300. In the embodiment of FIG. 3A, the display device 300 includes a flexible display 320 and a feedback board 310 under the flexible display 320. The flexible display 320 is to output an image, such as the user interface 130, and may be similar in functionality to the first display 110. However, both the user interface 130 and the first image 140 may be displayed simultaneously on the flexible display 320, with at least one of the user interface 130 and the first image 140 rendered to be at least partially transparent.

In addition, as described above, the flexible display 320 is composed of a flexible substrate that can bend, flex, conform, etc. The feedback board 310 may be any type of feedback system, such as a mechanical or electrical feedback system. The flexible display 320 and the feedback board 310 are explained in greater detail below with respect to FIG. 3B.

FIG. 3B is an example block diagram of a cross-sectional side-view of the display of FIG. 3A. As shown in FIG. 3B, the feedback board 310 may include a plurality of actuators 312 to provide at least one of an active and a passive tactile response. A surface of the flexible display 320 may be pressed and/or depressed by the user when interacting with the user interface 130. For example, the user may press one of the plurality of buttons or keys 132 displayed on a surface of the flexible display 320 and the feedback board 310 may output a tactile response at only the pressed portion of the surface of the flexible display 320. In one embodiment, each of the keys 132 may correspond to at least one of the plurality of actuators 312.

Embodiments of the actuator 312 may include any type of mechanical device for moving or controlling a mechanism or system. Examples of the actuators 312 may include electrical motors, pneumatic actuators, hydraulic actuators, linear actuators, comb drive, piezoelectric actuators and amplified piezoelectric actuators, thermal bimorphs, micromirror devices, electroactive polymers, magnetic devices, and the like.

An example of the actuator 312 having the passive tactile response may include any material, device or system that stores mechanical energy and then releases at least some of the stored mechanical energy as motion. For example, FIG. 3B shows the actuator 312 to be an elastic material, such as a coiled spring, that may compress in response to pressure or force exerted by the user and then decompress when released.

An example of the actuator 312 having the active the tactile response may include any material, device or system that is operated by a source of energy, usually in the form of an electric current, hydraulic fluid pressure or pneumatic pressure, and converts that energy into some type of applied force, vibration, and/or motion, in response to the pressure or force exerted by the user. In embodiments, the response may be applied to only a portion of the flexible display 310 at which the pressure or force is exerted by the user. in one embodiment, the actuator 312 having the active the tactile response may begin to push back even before the button of user interface 130 has been fully pressed.

In FIG. 3B, when pressure is applied by the user, only a portion of the surface of the flexible display 320 is shown to bend and only a corresponding actuator 312 underneath the bent surface is shown to compress. As such, the surrounding surface of the flexible display 320 as well as the surrounding actuators 312 are not affected, thus minimizing strain and/or distortion to a surrounding surface of the flexible display 320. In addition, when the pressure is released by the user, the actuator 312 may decompress and push back, resulting in the bent surface of the flexible display 320 becoming flat again.

While FIG. 3B shows the actuator 312 only moving in an up-and-down or perpendicular direction with respect to the surface of the flexible display 320, embodiments of the actuators 312 may move in other directions as well, such as a side-to-side or parallel direction with respect to the surface of the flexible display 320.

In addition, the flexible display 320 and/or the feedback board 310 may limit a depth to which the surface of the flexible display 320 may be pressed, based on an image threshold or user preference. The image threshold may relate to a depth at which the image displayed on the flexible display 230 becomes visibly distorted.

In one embodiment, the transparent second flexible display 110 may optionally be placed over the flexible display 320 to provide the user interface 130 and/or touch sensitive surface. For example, the touch sensitive surface may sense and communicate to the feedback board 310 that one of the keys 132 is being touched and/or pressed by the user.

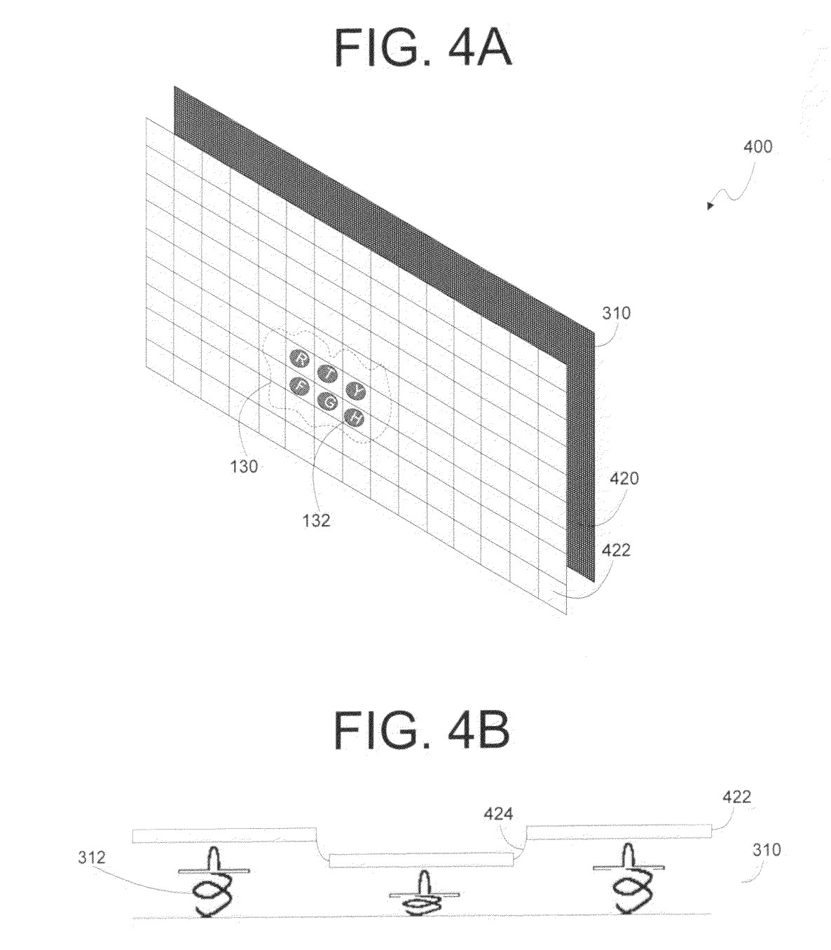

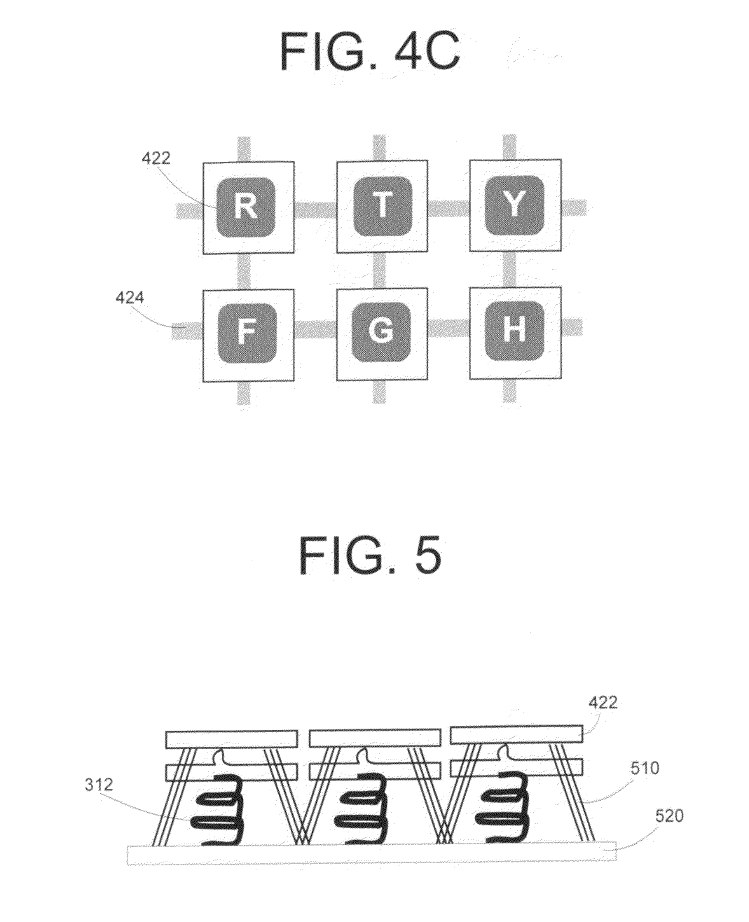

FIG. 4A is an example block diagram of a perspective view of yet another display device 400. The display device 400 may be similar to the display device 300 of FIG. 3A, except that a flexible display 420 is segmented into a plurality of segments 422. Each of the segments 422 may be pressed and/or depressed independently. Further, the segments 422 may not include substantially visible gaps therebetween.

As shown in FIG. 4A, the segments 422 may each correspond to a separate one of the keys 132 of the user interface 130. However, embodiments are not limited thereto. For example, the segments 422 may each also correspond to a plurality of the keys 132 or a portion of one of the keys 132.

The independent segments 422 may allow for the image threshold to be greater because the segments 422 may be pressed down to a greater depth without affecting neighboring segments 422, resulting in overall less image distortion.

FIG. 4B is an example block diagram of a cross-sectional side-view of the display of FIG. 4A. FIG. 4C is an example block diagram of an exposed top-view of the display of FIG. 4A. As shown in FIG. 4B, each of the segments 422 may move independently of one another and also correspond to a single one of the actuators 312. However, embodiments are not limited thereto. For example, at least one of segments 422 may also be correlated to a plurality of the actuators 312.

Further, as shown in FIGS. 4B and 4C, at least one of the segments 422 may include a flexible electrical connection 424 to at least another of the plurality of segments 422 under a surface of the segmented flexible display 420. The flexible electrical connections 424 and gaps between the segments 422 are not drawn to scale and exaggerated for the sake of clarity. The flexibility of the electrical connections 424 may allow the segments 422 to remain connected to each other despite the independent movements of the segments 422.

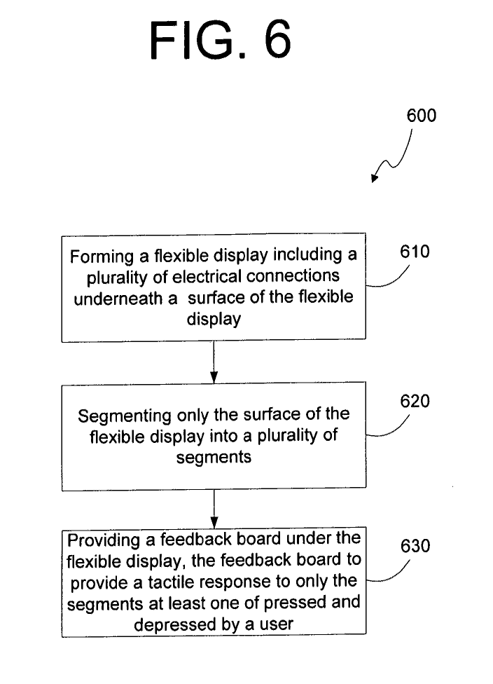

FIG. 5 is a flowchart of an example method 500 for forming the display device 400. At block 510, the flexible display 420 is formed including a plurality of the electrical connections 424 underneath a surface of the flexible display 420. Then, at block 520, only the surface of the flexible display 420 is segmented into a plurality of segments 422, such as by laser or die cutting. Therefore, the electrical connections 424 remain intact. Lastly, the feedback board 310 is provided under the flexible display 424. By keeping the electrical connections 424 intact and only segmenting the surface of the flexible display 420, the segments 422 may formed more quickly and at lower cost than if the individual segments 422 were electrically connected afterward.

According to the foregoing, embodiments provide a more efficient and/or convenient user interface for interacting with a computing device. For example, an entire surface of a display device may be utilized simultaneously for both user input and displaying images. In one embodiment, touch feedback may be provided independently and/or locally to different regions of the surface of the display, resulting in less image distortion and improved tactile responsiveness. Additionally, the feedback may be provided in at least a vertical direction with respect to a surface the display, thus more accurately conveying a button-like pressing action.

What is claimed is:

1. A display device, comprising:
a first display to output a first image; and
a second display to output a second image and to overlap the first display, wherein
the second display is transparent,
the second display includes a touch sensitive surface, and
at least one of the first and second image corresponds to a user interface.

2. The display device of claim 1, wherein,
a transparency of the second image is variable, and
the first image and the second image are simultaneously viewable by a user.

3. The display device of claim 2, wherein,
the first display is a high-resolution display and the second display is a low-resolution display, and
the second image corresponds to the user interface.

4. The display device of claim 3, wherein keys of the user interface for the second display are predefined.

5. The display device of claim 4, wherein,
the second display is at least one of removable and interchangeable with a third display,
the third display is transparent and includes a touch sensitive surface,
the third display to output a third image, where the third image is predefined and a transparency of the third image is variable.

6. The display device of claim 2, wherein,
the first and second displays are high-resolution displays, and
the first image corresponds to the user interface.

7. A display device, comprising:
a flexible display to output an image; and
a feedback board under the flexible display, the feedback board to output a tactile response at only a portion of a surface of the flexible display that is at least one of pressed and depressed by a user.

8. The display device of claim 7, wherein,
the image is a user interface including a plurality of keys,
the feedback board includes a plurality of actuators to provide at least one of an active and a passive tactile response, wherein
each of the keys corresponds to at least one of the plurality of actuators, and
only the corresponding actuator is to provide the tactile response when the portion of a surface of the flexible display displaying the key is at least one of pressed and depressed.

9. The display device of claim 8, wherein the corresponding actuator is to move in a direction at least one of parallel and perpendicular to a surface of the flexible display.

10. The display device of claim 9, wherein,
the flexible display is segmented into a plurality of segments,
each of the segments is to at least one of be pressed and depressed independently, and
the plurality of segments do not include substantially visible gaps therebetween.

11. The display device of claim 10, wherein,
each of the segments includes a flexible electrical connection to at least an other of the plurality of segments under a surface of the flexible display, and
each of the segments are to correspond to one of the keys.

12. The display device of claim 8, wherein the plurality of actuators include at least one of a spring-like, piezoelectric, magnetic, pneumatic component, and
the surface of the flexible display is to be pressed at a depth less than an image threshold related a visibility of the image.

13. The display device of claim 7, further comprising:
a transparent display over the flexible display to output a user interface, wherein
transparent display includes a touch sensitive surface.

14. A method for forming a display device, comprising:
forming a flexible display including a plurality of electrical connections underneath a surface of the flexible display, the flexible display to output a user interface;
segmenting only the surface of the flexible display into a plurality of segments; and
providing a feedback board under the flexible display, the feedback board to provide a tactile response to only the segments at least one of pressed and depressed by a user.

15. The method of claim 14, wherein the tactile response is in a direction at least one of parallel and perpendicular to the surface of the flexible display.
